(19) United States
(12) Patent Application Publication
(10) Pub. No.: US 2007/0126510 A1
(43) Pub. Date: Jun. 7, 2007

(54) Audio process circuit structure and process method thereof

(76) Inventor: Chih-Wei Tsai, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/488,821

(22) Filed: Jul. 19, 2006

(30) Foreign Application Priority Data
Jul. 27, 2005 (TW) 94125474

(51) Int. Cl. H03F 3/04

(52) U.S. Cl. 330/297

(57) ABSTRACT

This invention discloses an audio process circuit structure and process method applying to a video/audio apparatus that at least comprises an audio signal detection unit, an OR gate logic circuit unit, an AND gate logic circuit unit and an audio amplifier process unit. The audio signal detection unit also comprises a coupling capacitor, a signal amplifier circuit, a DC level shift circuit, a charge circuit and a switch circuit. This audio signal detection unit transfers different amplitude and frequency of the signal to be a high or low DC logic level signal. The high DC logic level signal is an audio signal and the low DC logic level signal is a noise. When the noise is inputted to the audio signal detection unit and a mute control signal is outputted by the audio signal detection unit to disable the audio amplifier process unit so as to prohibit the noise to output.

### FIELD OF THE INVENTION

The present invention generally relates to an audio process circuit structure and its method applying to a video/audio apparatus and more particularly to an audio signal detection unit in the audio process circuit structure filtering noises to keep a mute status without influencing audio output power of the video/audio apparatus.

### BACKGROUND OF THE INVENTION

Referring to FIG. 1, a schematic diagram of a conventional audio process circuit structure is illustrated. The audio process circuit structure comprises a low pass filter 11, an audio amplifier process unit 12, and an amplifier 13. The low pass filter 11 is used to distort the amplitude and frequency of the noise when an input audio signal 111 is a noise. The audio amplifier process unit 12 can be used to amplify an audio signal 112 and receive a system mute signal 121. An audio amplifier signal 122 can be also transmitted by the audio amplifier process unit 12 to the amplifier 13.

The input audio signal 111 can be an audio signal or a noise illustrated in FIG. 1. Due to the circuit characteristics of the audio process circuit structure, a signal with smallest amplitude and frequency is still produced from the inside of the audio process circuit structure without inputting an audio signal to the audio process circuit structure. The small signal is so called a noise. The noise can be lowered properly by the low pass filter 11 and is then outputted to the audio amplifier process unit 12. The processed noise can be amplified by the audio amplifier process unit 12 and is then transmitted to the amplifier 13. By the way mentioned above, obviously, the noise can not be eliminated completely by the low pass filter 11.

As described in FIG. 1, the conventional noise control is distorted by the low pass filter 11 of the audio process circuit structure to reduce the amplitude and frequency of the noise. However, the process may influence the output power of the audio signal 112 in the audio process circuit structure. The audio signal 112 with greater output power is really important for the audio process circuit structure. The noise caused by the audio process circuit structure or the audio signal produced from the audio process circuit structure while working normally, the input audio signal 111 is distorted by the low pass filter 11 to output the audio signal 112 to the audio amplifier process unit 12. The input audio signal 111 may be distorted through the process of the mentioned above. The audio signal 112 inputted by the audio amplifier process unit 12 is also an audio with distortion. Lastly, the audio signal 112 with greater output power can not be outputted by the amplifier 13 that the audio quality of the audio process circuit structure is also reduced.

Actually, without the audio signal, the noise is still amplified by the audio amplifier process unit and is then outputted by the amplifier while amplifying volume for the audio process circuit structure. Therefore, to resolve the noise produced from the amplifier when there is no audio signal inputted in the audio process circuit structure by providing an audio signal detection unit in the audio process circuit structure. A high or low DC logic level signal transmitted from the audio signal detection unit represents an acoustic signal or a noise. A mute control signal is transmitted to an audio amplifier process unit properly when the noise is produced. Hence, the audio amplifier process unit can be disabled to prohibit the noise to output to the amplifier.

### SUMMARY OF THE INVENTION

The object of the present invention is to provide an audio process circuit structure and its process method. The structure is applied to a video/audio apparatus and comprises an audio amplifier process unit and an amplifier. An audio signal detection unit is also added in the audio process circuit structure. At least one high or low DC (direct current) logic level signal is transmitted to an OR gate logic circuit unit when an external audio signal is received by the audio signal detection unit. A logic signal provided by the OR gate logic circuit unit is transmitted to an AND gate logic circuit unit. A mute control signal is transmitted to an audio amplifier process unit after the logic signal and an external system mute control signal are integrated into the AND gate logic circuit unit. By turning off the audio amplifier process unit, the noise produced by the audio process circuit structure cannot be outputted through the audio amplifier process unit.

The audio signal detection unit is divided into two parts, first is a detection circuit, and second is a switch circuit. The detection circuit comprises a coupling capacitor, a signal amplifier circuit, a DC level shift circuit, and a charge circuit. In the detection circuit, a direct current of an external audio signal is filtered through the coupling capacitor. The filtered external audio signal as the small signal is transmitted to the signal amplifier circuit to produce a small amplifier signal. Due to the influence of the circuit characteristics of the signal amplifier circuit, the level for the small amplifier signal skews that the audio process circuit structure is unable to determine an accuracy level of the small amplifier signal. Therefore, by using a DC level shift circuit to shift the level of the small amplifier signal, which has skewed already, to back the accuracy level of the audio process circuit structure and an adjustment level signal is then produced. The adjustment level signal is transformed by the charge circuit into different DC voltages and a high or low DC logic level signal is outputted that the ON or Off can be handled by the switch circuit.

By the circuit characteristics of the audio signal detection unit of the mentioned above, an input signal with higher amplitude and frequency is obtained by the detection circuit that enables the switch circuit to output a high DC logic level signal when an acoustic signal is inputted. Comparatively, an input signal with lower amplitude and frequency is obtained by the detection circuit that enables the switch circuit to output a low DC logic level signal when a noise is inputted. Therefore, the high DC logic level signal outputted from the audio signal detection unit represents the audio signal input and low DC logic level signal outputted from the audio signal detection unit represents the noise input. The high or low DC logic level signal may enable an external system mute signal in the OR gate logic circuit unit, the AND gate logic circuit unit, and the audio process circuit structure to be logically processed. A mute control signal is acquired by the audio amplifier process unit properly. The mute control signal may help the audio amplifier process unit to turn on and turn off properly. In another word, the audio amplifier process unit is turned off when the noise is produced. Therefore, by the way mentioned above, the efficiency of the amplifier can be improved without inputting the audio signal, the noise can also be eliminated.

### BRIEF DESCRIPTION OF THE DRAWINGS

FIG. 1 is a schematic diagram of a conventional audio process circuit structure;

FIG. 2 is a schematic diagram of an audio process circuit structure according to an embodiment of the present invention;

FIG. 3 is a schematic diagram of an audio signal detection unit according to an embodiment of the present invention;

FIG. 4 is a schematic diagram of a detection circuit according to an embodiment of the present invention;

FIG. 5 is a schematic diagram of a switch circuit according to an embodiment of the present invention;

FIG. 6 is a schematic diagram of an audio process circuit according to an embodiment of the present invention; and

FIG. 7 is a flowchart of an audio process method according to an embodiment of the present invention.

### DETAILED DESCRIPTION OF THE PREFERRED EMBODIMENTS

To make it easier for our examiner to understand the objective of the invention, its innovative features and performance, a detailed description and technical characteristics of the present invention are described together with the drawings as follows.

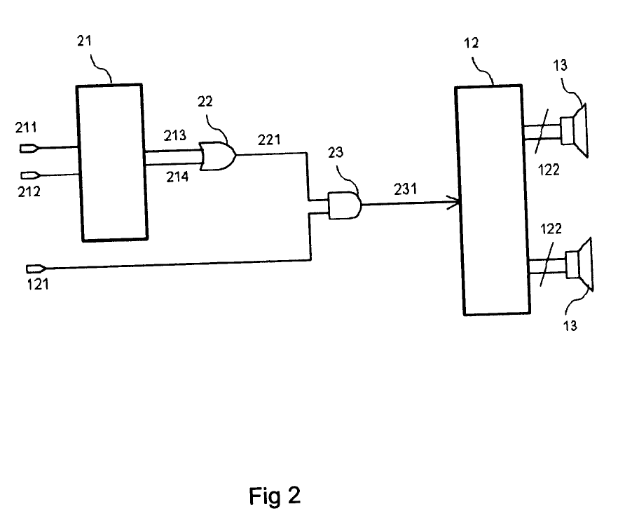

Referring to FIG. 2, a schematic diagram of an audio process circuit structure according to an embodiment of the present invention is illustrated. The structure comprises an audio amplifier process unit 12 and an amplifier 13. An audio signal detection unit 21, an OR gate logic circuit unit 22, and an AND gate logic circuit unit 23. The audio signal detection unit 21 is used to receive audio signals 211, 212. The audio signals 211, 212 can be an acoustic signal or a noise. Audio detection signals 213, 214 are transmitted to the OR gate logic circuit unit 22 after the audio signals 211, 212 are processed by the audio signal detection unit 21. An integrated audio detection signal 221 is transmitted to the AND gate logic circuit unit 23 after the audio detection signals 213, 214 are logically processed by the OR gate logic circuit unit 22. A mute control signal 231 is transmitted to the audio amplifier process unit 12 after the integrated audio detection signal 221 and a mute signal 121 of the audio process circuit structure are then transmitted to the AND gate logic circuit unit 23 for logically processing. Therefore, the audio amplifier process unit 12 can be used through the mute control signal 231 to turn on and turn off properly. In other words, the audio amplifier process unit is turned off and the audio amplifier signal 122 is prohibited to output to the amplifier 13 if the audio signals 211, 212 are noises. The audio amplifier process unit is turned on and the audio amplifier signal 122 is outputted to the amplifier 13 if the audio signals 211, 212 are acoustic signals.

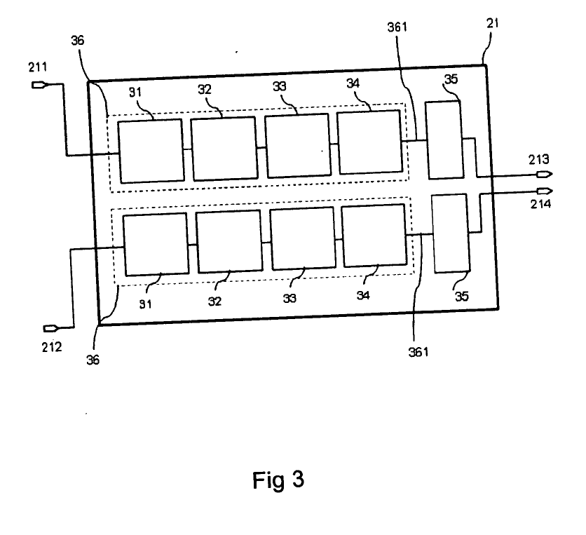

Referring to FIG. 3, a schematic diagram of an audio signal detection unit according to an embodiment of the present invention is illustrated. The audio signal detection unit 21 comprises two detection circuits 36 and two switch circuits 35. The detection circuit 46 comprises a coupling capacitor 31, a signal amplifier circuit 32, a DC level shift circuit 33, and a charge circuit 34. A high DC logic level signal sent from the audio signal detection unit 21 represents the acoustic signal and a low DC logic level signal sent from the audio signal detection unit 21 represents the noise after the audio signals 211, 212 are received by the audio signal detection unit 21. In another word, the audio detection signals 213, 214 are transmitted by the audio signal detection unit 21 to next stage.

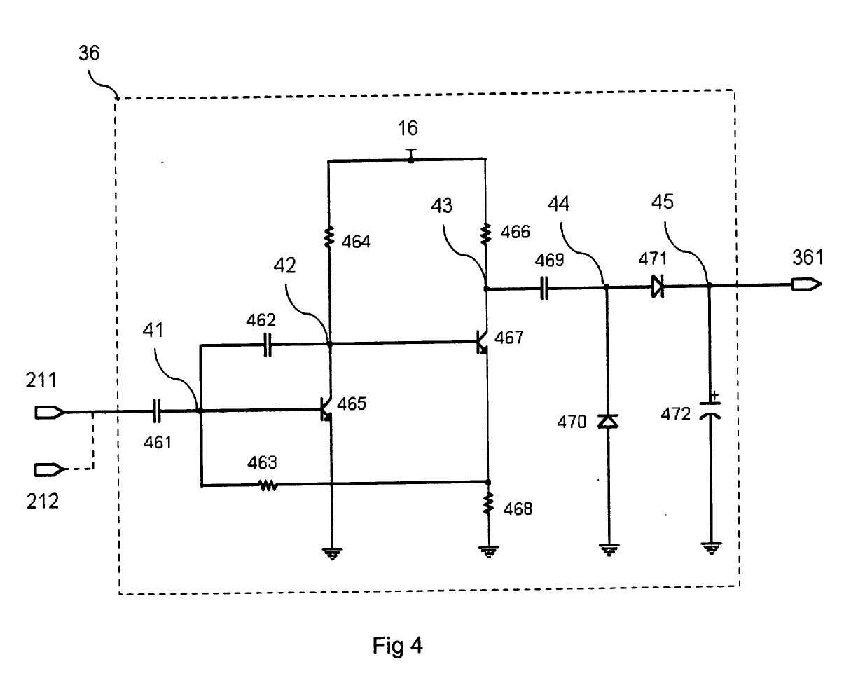

Referring to FIG. 4, a schematic diagram of a detection circuit according to an embodiment of the present invention is illustrated. In accordance with the circuit structure as shown in FIG. 4, the function of the detection circuit 36 can be accomplished. The detection circuit 36 comprises two bipolar transistors 465, 467, two PN junction diodes 470, 471, four carbon film fixed resistors (CR) 463, 464, 466, 468, four capacitors 461, 462, 469, 472. A small signal can be detected by a signal detection node 41 through the filtered signal of the capacitor 461 after the audio signals 211, 212 are received by the detection circuit 36. A small amplifier signal can be detected by a signal detection node 42 through the amplifying of the capacitor 465. A small amplifier signal which the level has skewed can be detected by a signal detection node 43 through the feedback voltage shift of the capacitor 467. An adjustment level signal can be detected by a signal detection node 44 through the rectifying of the capacitor 469. A DC logic level signal can be detected by a signal detection node 45 through the diodes 470, 477 and the capacitor 472. The DC logic level signal is transmitted by the detection circuit 36 to next stage.

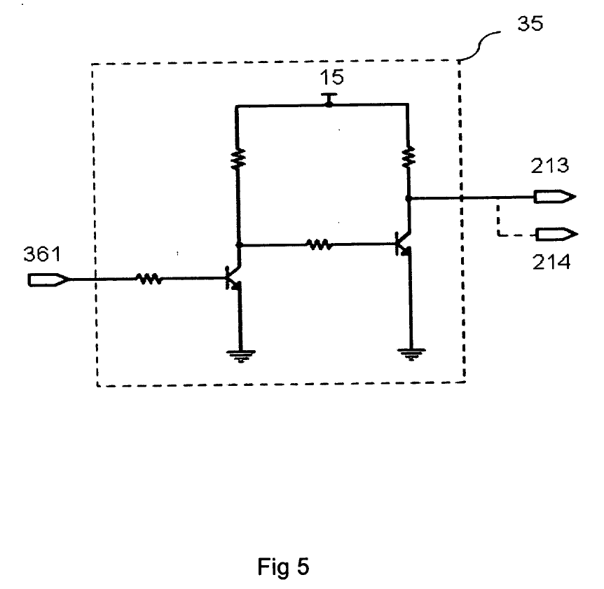

Referring to FIG. 5, a schematic diagram of a switch circuit according to an embodiment of the present invention is illustrated. In accordance with the circuit structure as shown in FIG. 5, the function of the switch circuit 35 can be accomplished. The switch circuit 35 comprises two bipolar transistors and four carbon film fixed resistors. As shown in FIG. 5, the audio detection signals 213, 214 can be adjusted by the switch circuit 35 to be a high DC logic level signal when a higher DC logic level signal 361 is received by the switch circuit 35. On the other hand, the audio detection signals 213, 214 can be adjusted by the switch circuit 35 to be a low DC logic level signal when a lower DC logic level signal 361 is received by the switch circuit 35.

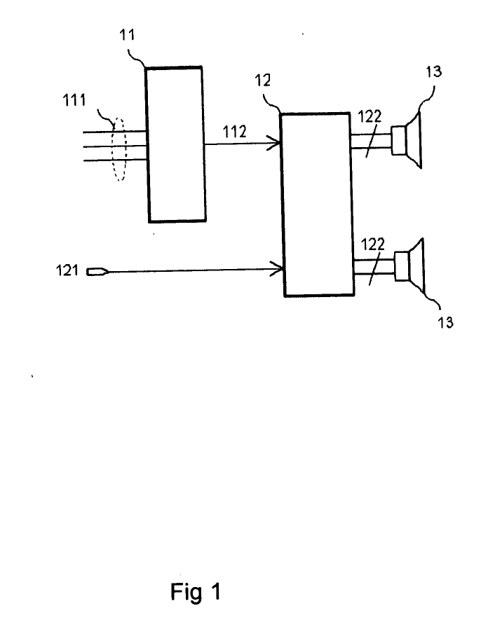

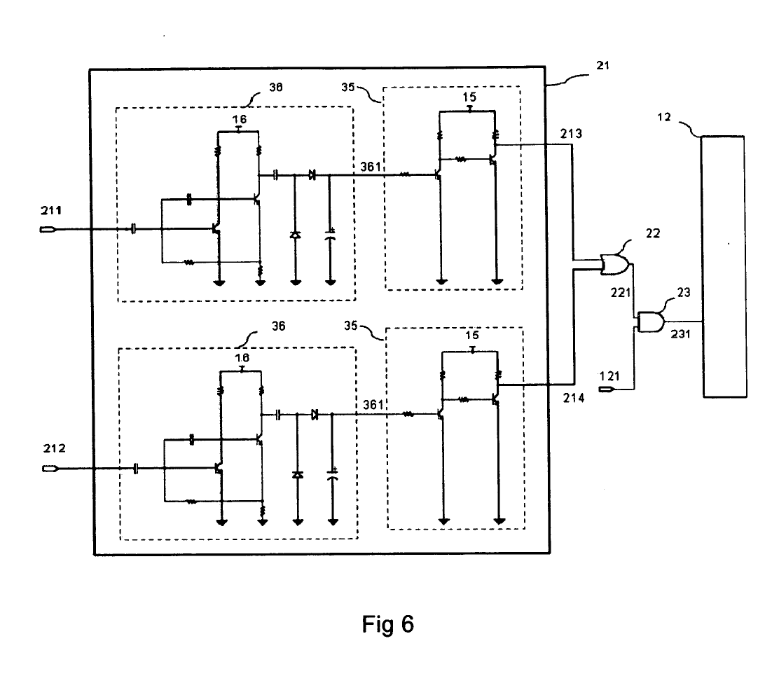

Referring to FIG. 6, a schematic diagram of an audio process circuit according to an embodiment of the present invention is illustrated. In accordance with FIG. 6, the audio process circuit structure as shown in FIG. 1 can be accomplished completely. The audio detection signal 213, 214 are transmitted to the OR gate logic circuit unit 22 after the audio signals 211, 212 are processed by the audio signal detection unit 21. An integrated audio detection signal 221 is transmitted to the AND gate logic circuit unit 23 after the audio detection signals 213, 214 are logically processed by the OR gate logic circuit unit 22. A mute control signal 231 is transmitted to the audio amplifier process unit 12 after the integrated audio detection signal 221 and the system mute signal 121 of the audio process circuit structure are logically processed by the AND gate logic circuit unit 23. Therefore, the audio amplifier process unit 12 can be used to turn on and turn off properly via the mute control signal 231. In other words, the audio amplifier process unit 12 is turned off and the audio amplifier signal 122 is prohibited to output to the amplifier 13 if the audio signals 211, 212 are noises. The audio amplifier process unit 12 is turned on and the audio amplifier signal 122 is outputted to the amplifier 13 if the audio signals 211, 212 are acoustic signals. The audio signal detection unit 21 comprises two detection circuits 36 and two switch circuits 35. The audio detection signals 213, 214 can be adjusted by the switch circuit 35 to be a high DC logic level signal when a higher DC logic level signal 361 is received by the switch circuit 35. On the other hand, the audio detection signals 213, 214 can be adjusted by the switch circuit 35 to be a low DC logic level signal when a lower DC logic level signal 361 is received by the switch circuit 35. In another word, the outputs of the audio detection signals 213, 214 are zero volts if the DC logic level signal 361 is lower 0.7 volt. Therefore, the audio signal detection unit 21 can effectively determine acoustic signals or noises to improve control properly.

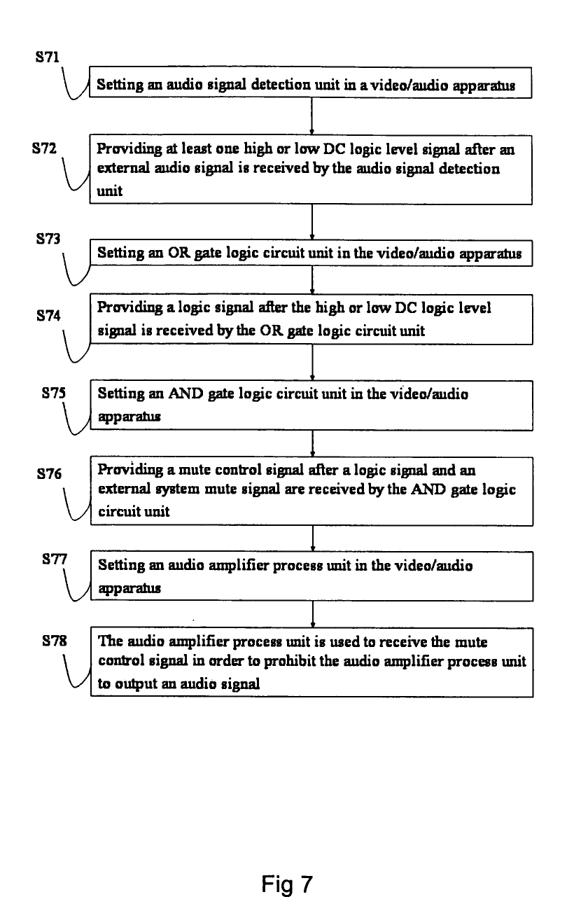

Referring to FIG. 7, a flowchart of an audio process method according to an embodiment of the present invention is illustrated. The method comprises the following steps of: setting an audio signal detection unit in a video/audio apparatus S71, providing at least one high or low DC logic level signal after an external audio signal is received by the audio signal detection unit S72, setting an OR gate logic circuit unit in the video/audio apparatus S73, providing a logic signal after the high or low DC logic level signal is received by the OR gate logic circuit unit S74, setting an AND gate logic circuit unit in the video/audio apparatus S75, providing a mute control signal after a logic signal and an external system mute signal are received by the AND gate logic circuit unit S76, setting an audio amplifier process unit in the video/audio apparatus S77, and the audio amplifier process unit is used to receive the mute control signal in order to prohibit the audio amplifier process unit to output an audio signal S78. By the way mentioned above, the acoustic signals or noises can be effectively determined.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

In summation of the description above, the present invention is novel and useful and definite enhances the performance over the conventional structure and further complies with the patent application requirements and is submitted to the Patent and Trademark Office for review and granting of the commensurate patent rights.

What is claimed is:

1. An audio process circuit structure, applied to a video/audio apparatus, comprising:
an audio signal detection unit receiving an external audio signal to provide at least one high or low DC logic level signal;
an OR gate logic circuit unit receiving said high or low DC logic level signal to provide an logic signal;
an AND gate logic circuit unit receiving said logic signal and receiving an external system mute signal to provide a mute control signal; and
an audio amplifier process unit receiving said mute control signal to prohibit said audio amplifier process unit to output an audio signal.

2. The audio process structure of claim 1, wherein said audio signal detection unit at least comprises:
a coupling capacitor receiving said external audio signal;
a signal amplifier circuit coupling to said coupling capacitor;
a DC level shift circuit coupling to said signal amplifier circuit;
a charge circuit coupling to said DC level shift circuit; and
a switch circuit coupling to said charge circuit.

3. The audio process structure of claim 1, wherein said video/audio apparatus is a LCD TV.

4. The audio process structure of claim 1, wherein said external audio signal is an audio signal of said video-audio apparatus.

5. The audio process structure of claim 1, wherein said external system mute signal is a mute signal of said video-audio apparatus.

6. The audio process structure of claim 2, wherein said coupling capacitor provides a small signal.

7. The audio process structure of claim 6, wherein said signal amplifier circuit receives said small signal and provides a small amplifier signal.

8. The audio process structure of claim 7, wherein said DC level shift circuit receives said small amplifier signal and provides an adjustment level signal.

9. The audio process structure of claim 8, wherein said charge circuit receives said adjustment level signal and provides a DC logic level signal.

10. The audio process structure of claim 9, wherein said switch circuit receives said DC logic level signal.

11. An audio process method, applied to a video/audio apparatus, comprising steps of:
setting an audio signal detection unit in said video/audio apparatus, said audio signal detection unit receiving an external audio signal to provide at least one high or low DC logic level signal;
setting a OR gate logic circuit unit in said video/audio apparatus, said OR gate logic circuit unit receiving said high or low DC logic level signal to provide a logic signal;
setting an AND gate logic circuit in said video/audio apparatus, said AND gate logic circuit receiving said logic signal and receiving an external system mute signal to provide a mute control signal; and
setting an audio amplifier process unit in said video/audio apparatus, said audio amplifier process unit receiving said mute control signal to prohibit said audio amplifier process unit to output an audio signal.

12. The audio process method of claim 11, further comprising providing a LCD TV to be said video/audio apparatus.

13. The audio process method of claim 11, further comprising providing an audio signal of said video/audio apparatus to be said external audio signal.

14. The audio process method of claim 11, further comprising providing a mute signal of said video/audio apparatus to be said external system mute signal.
